(19) United States
(12) Patent Application Publication
(10) Pub. No.: US 2014/0374868 A1
(43) Pub. Date: Dec. 25, 2014

(54) IMAGE SENSOR AND METHOD OF MANUFACTURING THE SAME

(71) Applicant: Samsung Electronics Co., Ltd., Suwon-si (KR)

(72) Inventors: Tae Hun LEE, Suwon-si (KR); Hee Geun JEONG, Suwon-si (KR); Byung Jun PARK, Yongin-si (KR); Eun Kyung PARK, Seoul (KR); Jung Chak AHN, Yongin-si (KR); Duck Hyung LEE, Seongnam-si (KR); Gye Hun CHOI, Incheon (KR)

(73) Assignee: Samsung Electronics Co., Ltd.

(21) Appl. No.: 14/307,620

(22) Filed: Jun. 18, 2014

(30) Foreign Application Priority Data
Jun. 20, 2013 (KR) 10-2013-0070886

(51) Int. Cl. H01L 27/146

(52) U.S. Cl. CPC H01L 27/1463
USPC 257/446; 438/73

(57) ABSTRACT

An image sensor includes a plurality of photo detectors and a plurality of trench isolations configured to isolate the photo detectors from each other. Each of the trench isolations includes a plurality of films in a multi-layer structure. A method of manufacturing an image sensor includes forming a plurality of trench isolations to isolate a plurality of photo detectors from each other, forming a first film in each of the trench isolations, and forming a second film that constructs a multi-layer structure together with the first film.

### CROSS-REFERENCE TO RELATED APPLICATIONS

This application claims the benefit of priority under 35 U.S.C. §119(a) to Korean Patent Application No. 10-2013-0070886, filed Jun. 20, 2013, the content of which is incorporated herein in its entirety by reference.

### BACKGROUND

1. Field

Embodiments of the inventive concept relate to an image sensor, and more particularly, to an image sensor including a trench isolation including a plurality of films in a multi-layer structure and a method of manufacturing the same.

2. Description of the Related Art

An image sensor is a device that converts an optical image into an electrical image. Methods of receiving light in the image sensor include front side illumination (FSI) and back side illumination (BSI). An image sensor using the BSI receives more light and has a different structure than an image sensor using the FSI.

As the size of a BSI image sensor decreases, the BSI image sensor may have a crosstalk problem. The crosstalk may be optical crosstalk, occurring when incident light passed through a color filter is transmitted to an adjacent photo detector, or electrical crosstalk, occurring when an electron hole pair generated in a depletion region of a current photo detector is transmitted to an adjacent photo detector. The crosstalk may cause image distortion.

### SUMMARY

The present inventive concept provides an image sensor.

The present inventive concept also provides a method of manufacturing such an image sensor.

The present inventive concept also provides an image processing system that includes such an image sensor.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing an image sensor that includes a plurality of photo detectors and a plurality of trench isolations configured to isolate the photo detectors from each other. Each of the trench isolations includes a plurality of films in a multi-layer structure.

The films may include a first oxide film formed at an inner side of each of the plurality of trench isolations and a poly silicon film formed at an inner side of the first oxide film. The films may further include a nitride film formed between the first oxide film and the poly silicon film. The films may further include a second oxide film formed between the nitride film and the poly silicon film.

Alternatively, the films may include a first nitride film formed at an inner side of each of the plurality of trench isolations and a poly silicon film formed at an inner side of the first nitride film. The films may further include an oxide film formed between the first nitride film and the poly silicon film. The films may further include a second nitride film formed between the oxide film and the poly silicon film.

As an alternative, the films may include an oxide film formed at an inner side of each of the plurality of trench isolations and a nitride film formed at an inner side of the oxide film.

As another alternative, the films may include a nitride film formed at an inner side of each of the plurality of trench isolations and an oxide film formed at an inner side of the nitride film.

As another alternative, the films may include an oxide film having a negative fixed charge. The oxide film may have a stack structure in which a fixed charge film having the negative fixed charge and a silicon oxide film are stacked. The fixed charge film may be a hafnium oxide film, an aluminum oxide film, a zirconium oxide film, a tantalum oxide film, or a titanium oxide film.

As another alternative, the films may include a poly silicon film and the poly silicon film may be formed of doped poly silicon.

The foregoing and/or other features and utilities of the present general inventive concept also provide an image processing system that includes the above-described image sensor and a processor configured to process image signals output from the image sensor.

The foregoing and/or other features and utilities of the present general inventive concept also provide a method of manufacturing an image sensor. The method includes forming a plurality of trench isolations to isolate a plurality of photo detectors from each other, forming a first film in each of the trench isolations, and forming a second film that constructs a multi-layer structure together with the first film.

The foregoing and/or other features and utilities of the present general inventive concept also provide an image sensor that includes a first photo detector coupled to a first lens and a second photo detector coupled to a second lens, and a trench isolation disposed between the first photo detector and the second photo detector and having a material that, in response to a light being incident through the first lens, prevents the light from being input to the second photo detector.

The material, in response to an electron hole pair being generated in a depletion region of the second photo detector, may prevent the electron hole pair from being transmitted to the first photo detector.

The material may include a first material having a first refractive index and a second material having a second refractive index.

The material may form a hole accumulation layer.

The material may include a fixed charge film having a negative fixed charge.

### BRIEF DESCRIPTION OF THE DRAWINGS

These and/or other features and utilities of the present general inventive concept will become apparent and more readily appreciated from the following of the embodiments, taken in conjunction with the accompanying drawings of which:

FIG. 1 is a cross-sectional view of a pixel area according to an embodiment of the present inventive concept;

FIG. 2 is a cross-sectional view of a pixel area according to an embodiment of the present inventive concept;

FIG. 3 is a cross-sectional view of a pixel area according to an embodiment of the present inventive concept;

FIGS. 4 through 9 are diagrams that illustrate a method of manufacturing the pixel area illustrated in FIG. 1;

FIG. 10 is a flowchart of a method of manufacturing an image sensor according to an embodiment of the present inventive concept;

FIG. 11 is a block diagram of an image sensor including the pixel area illustrated in FIG. 1,

FIG. 12 is a block diagram of an image processing system including the image sensor illustrated in FIG. 11 according to an embodiment of the present inventive concept; and

FIG. 13 is a block diagram of an image processing system including the image sensor illustrated in FIG. 11 according to an embodiment of the present inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept while referring to the figures.

It is understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It is understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the present general inventive concept. As used herein, the singular forms “a”, “an” and “the” are intended to include the plural forms as well, unless the context clearly indicates otherwise. It is further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the present general inventive concept belongs. It is further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

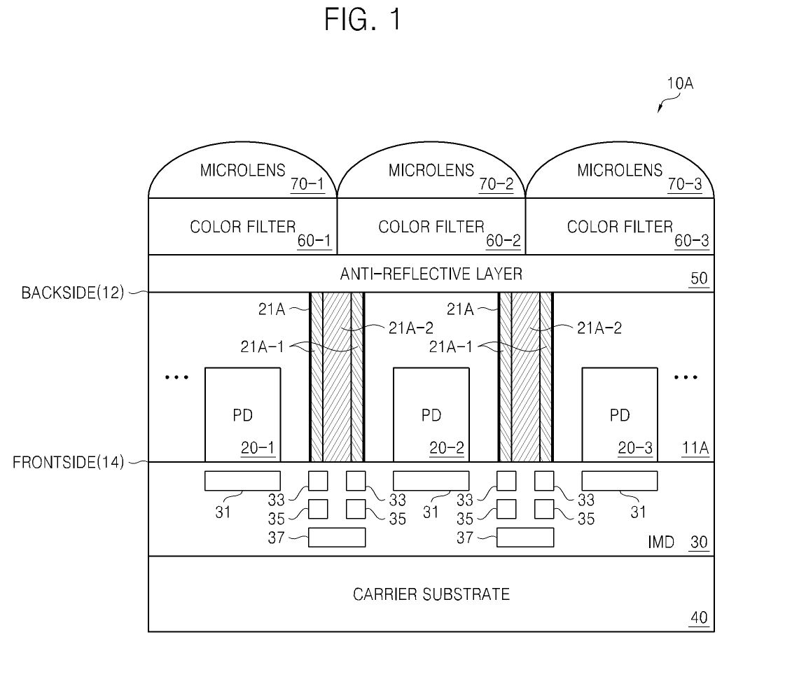

FIG. 1 is a cross-sectional view of a pixel area 10A according to an embodiment of the present inventive concept. The pixel area 10A may include an epitaxial layer 11A, an inter-metal dielectric (IMD) layer 30, a carrier substrate 40, an anti-reflective layer 50, color filters 60-1 through 60-3, and microlenses 70-1 through 70-3.

Photo detectors 20-1 through 20-3 and trench isolations 21A isolating the photo detectors 20-1 through 20-3 from each other may be formed in the epitaxial layer 11A. The photo detectors 20-1 through 20-3 may generate photocharges in response to light incident from outside. Each of the photo detectors 20-1 through 20-3 may be a photosensitive element that may be implemented, for example, as a photodiode, a phototransistor, a photogate, or a pinned photodiode (PPD).

Each of the trench isolations 21A may be, for example, a deep trench isolation (DTI). Each trench isolation 21A may include a plurality of films 21A-1 and 21A-2 in a multi-layer structure.

The first film 21A-1 may be formed at the inner side of the trench isolation 21A. The second film 21A-2 may be formed at the inner side of the first film 21A-1. According to an embodiment, the first film 21A-1 may be, for example, an oxide film and the second film 21A-2 may be, for example, a poly silicon film.

Alternatively, the first film 21A-1 may be, for example, a nitride film and the second film 21A-2 may be, for example, a poly silicon film. The nitride film may be, for example, a silicon nitride film.

The poly silicon film may be formed, for example, of doped poly silicon. In this case, a hole accumulation layer (not illustrated) may be formed on the sidewall of the trench isolation 21A by applying a negative voltage to the doped poly silicon. The hole accumulation layer may suppress the occurrence of dark current. Alternatively, the first film 21A-1 may be, for example, a nitride film and the second film 21A-2 may be, for example, an oxide film.

The first film 21A-1 and the second film 21A-2 may have different refractive indexes. In this case, except for light incident through the microlens (e.g., 70-2) and the color filter (e.g., 60-2) that may correspond to a particular photo detector (e.g., 20-2), external light input to the particular photo detector (e.g., 20-2) may be totally reflected.

For example, the trench isolations 21A may totally reflect light incident through the microlens 70-1 and the color filter 60-1 and light incident through the microlens 70-3 and the color filter 60-3, thereby preventing the light from being input to the photo detector 20-2. In other words, optical crosstalk may be reduced due to the trench isolations 21A.

In addition, the trench isolations 21A may prevent an electron hole pair generated in a depletion region of the particular photo detector 20-2 from being transmitted to the adjacent photo detectors 20-1 and 20-3. In other words, electrical crosstalk may be reduced due to the trench isolations 21A.

According to an embodiment, when the first film 21A-1 or the second film 21A-2 is an oxide film, the oxide film may have a negative fixed charge. The oxide film may be, for example, a hafnium oxide film, an aluminum oxide film, a zirconium oxide film, a tantalum oxide film, or a titanium oxide film. In this case, the oxide film may suppress the generation of charges in the trench isolations 21A and may block the charges from flowing into the photo detectors 20-1 through 20-3. In other words, dark current may be reduced due to the trench isolations 21A.

Alternatively, when the first film 21A-1 or the second film 21A-2 is an oxide film, the oxide film may have a stack structure (not illustrated) in which a fixed charge film with a negative fixed charge and a silicon oxide film are stacked. The fixed charge film may be, for example, a hafnium oxide film, an aluminum oxide film, a zirconium oxide film, a tantalum oxide film, or a titanium oxide film.

The trench isolations 21A may be formed from a frontside 14 of the epitaxial layer 11A toward a backside 12 of the epitaxial layer 11A. Alternatively, the trench isolations 21A may be formed from the backside 12 of the epitaxial layer 11A toward the frontside 14 of the epitaxial layer 11A.

The IMD layer 30 may include metals 31, 33, 35, and 37. Electrical wiring necessary for the sensing operation of the pixel area 10A may be formed by the metals 31, 33, 35, and 37. According to an embodiment, the metals 31, 33, 35, and 37 may reflect light incident through the photo detectors 20-1 through 20-3 to the photo detectors 20-1 through 20-3. The metals 31, 33, 35, and 37 may be, for example, copper, titanium, or titanium nitride. The carrier substrate 40 may be, for example, a silicon substrate.

The anti-reflective layer 50 may reduce the reflection of light at the surface of the pixel area 10A. The anti-reflective layer 50 may improve the contrast of an image sensed by the photo detectors 20-1 through 20-3.

The color filters 60-1 through 60-3 may pass light having wavelengths in the visible spectrum. Each of the color filters 60-1 through 60-3 may be, for example, a red filter, a green filter, or a blue filter. The red filter may pass light in a range of wavelengths that correspond to a red color in the visible spectrum. The green filter may pass light in a range of wavelengths that correspond to a green color in the visible spectrum. The blue filter may pass light in a range of wavelengths that correspond to a blue color in the visible spectrum.

Alternatively, each of the color filters 60-1 through 60-3 may be, for example, a cyan filter, a magenta filter, or a yellow filter. The cyan filter may pass light in a wavelength range of about 450 to 550 nm in the visible spectrum. The magenta filter may pass light in a wavelength range of about 400 to 480 nm in the visible spectrum. The yellow filter may pass light in a wavelength range of about 500 to 600 nm in the visible spectrum.

The microlenses 70-1 through 70-3 may focus incident light. According to an embodiment, the pixel area 10A may exclude the microlenses 70-1 through 70-3.

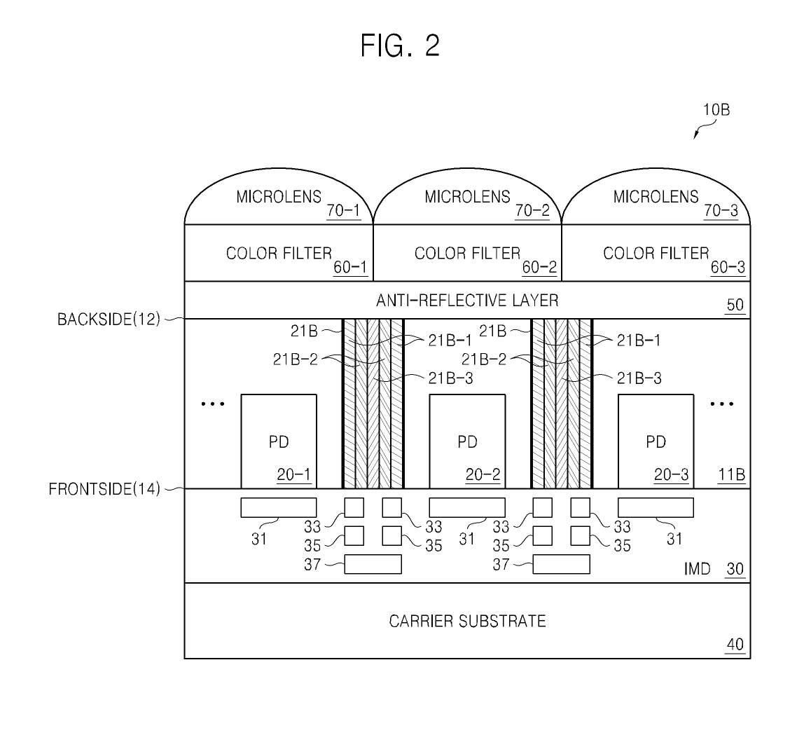

FIG. 2 is a cross-sectional view of a pixel area 10B according to an embodiment of the present inventive concept. Referring to FIGS. 1 and 2, the pixel area 10B may include an epitaxial layer 11B, the IMD layer 30, the carrier substrate 40, the anti-reflective layer 50, the color filters 60-1 through 60-3, and the microlenses 70-1 through 70-3.

The epitaxial layer 11B may include trench isolations 21B. Each of the trench isolations 21B may be, for example, a DTI. The trench isolations 21B may include more films than the trench isolations 21A.

A first film 21B-1 may be formed at the inner side of each of the trench isolations 21B. A second film 21B-2 may be formed between the first film 21B-1 and a third film 21B-3. The third film 21B-3 may be formed at the inner side of the first and second films 21B-1 and 21B-2. The first film 21B-1 may be, for example, an oxide film, the second film 21B-2 may be, for example, a nitride film, and the third film 21B-3 may be, for example, a poly silicon film. Alternatively, the first film 21B-1 may be, for example, a nitride film, the second film 21B-2 may be, for example, an oxide film, and the third film 21B-3 may be, for example, a poly silicon film.

The oxide film used in each of the trench isolations 21B may have a negative fixed charge. The oxide film may be, for example, a hafnium oxide film, an aluminum oxide film, a zirconium oxide film, a tantalum oxide film, or a titanium oxide film. In this case, the oxide film may suppress the generation of charges in the trench isolations 21B and may block the charges from flowing into the photo detectors 20-1 through 20-3. In other words, dark current may be reduced due to the trench isolations 21B.

Alternatively, the oxide film used in each of the trench isolation 21B may have a stack structure (not illustrated) in which a fixed charge film with a negative fixed charge and a silicon oxide film are stacked. The fixed charge film may be, for example, a hafnium oxide film, an aluminum oxide film, a zirconium oxide film, a tantalum oxide film, or a titanium oxide film.

The poly silicon film used in each of the trench isolations 21B may be formed, for example, of doped poly silicon. In this case, a hole accumulation layer (not illustrated) may be formed on the sidewall of each of the trench isolations 21A by applying a negative voltage to the doped poly silicon. The hole accumulation layer may suppress the occurrence of dark current.

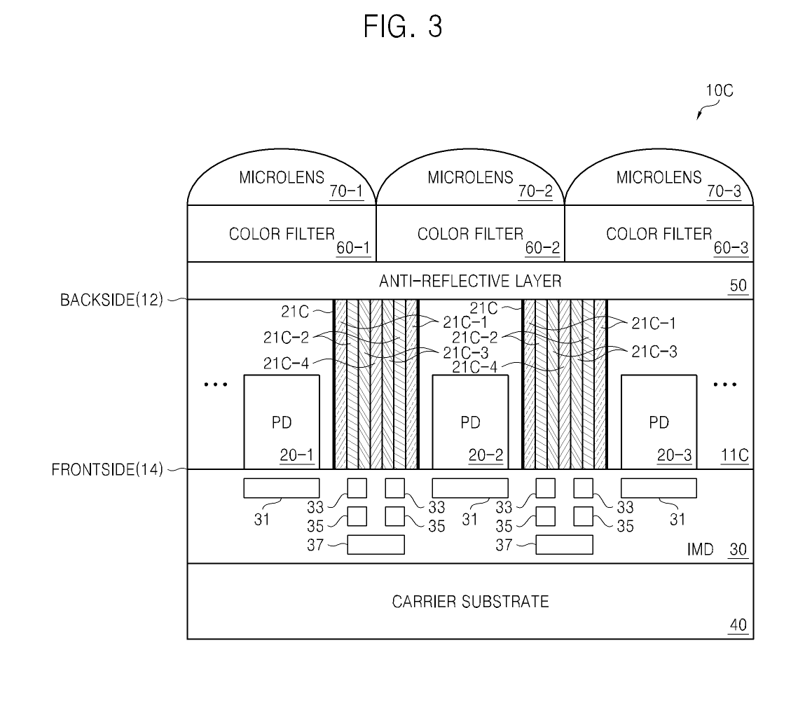

FIG. 3 is a cross-sectional view of a pixel area 100 according to an embodiment of the present inventive concept. Referring to FIGS. 1 through 3, the pixel area 100 may include an epitaxial layer 11C, the IMD layer 30, the carrier substrate 40, the anti-reflective layer 50, the color filters 60-1 through 60-3, and the microlenses 70-1 through 70-3.

The epitaxial layer 110 may include trench isolations 21C. Each of the trench isolations 21C may be, for example, a DTI. The trench isolations 21C may include more films than the trench isolations 21B.

A first film 210-1 may be formed at the inner side of each of the trench isolation 21C. A second film 21C-2 may be formed between the first film 210-1 and a third film 21C-3. The third film 21C-3 may be formed between the second film 21C-2 and a fourth film 21C-4. The fourth film 21C-4 may be formed at the inner side of the first through third films 210-1 through 21C-3.

The first film 21C-1 may be, for example, an oxide film, the second film 21C-2 may be, for example, a nitride film, the third film 21C-3 may be, for example, an oxide film, and the fourth film 21C-4 may be, for example, a poly silicon film. Alternatively, the first film 21C-1 may be, for example, a nitride film, the second film 21C-2 may be, for example, an oxide film, the third film 21C-3 may be, for example, a nitride film, and the fourth film 21C-4 may be, for example, a poly silicon film.

The oxide film used in each of the trench isolations 21C may have a negative fixed charge. The oxide film may be, for example, a hafnium oxide film, an aluminum oxide film, a zirconium oxide film, a tantalum oxide film, or a titanium oxide film. In this case, the oxide film may suppress the generation of charges in the trench isolations 21C and may block the charges from flowing into the photo detectors 20-1 through 20-3. In other words, dark current may be reduced due to the trench isolations 21C.

Alternatively, the oxide film used in each of the trench isolations 21C may have a stack structure (not illustrated) in which a fixed charge film with a negative fixed charge and a silicon oxide film are stacked. The fixed charge film may be, for example, a hafnium oxide film, an aluminum oxide film, a zirconium oxide film, a tantalum oxide film, or a titanium oxide film.

The poly silicon film used in each of the trench isolations 21C may be formed, for example, of doped poly silicon. In this case, a hole accumulation layer (not illustrated) may be formed on the sidewall of each of the trench isolations 21C by applying a negative voltage to the doped poly silicon. The hole accumulation layer may suppress the occurrence of dark current.

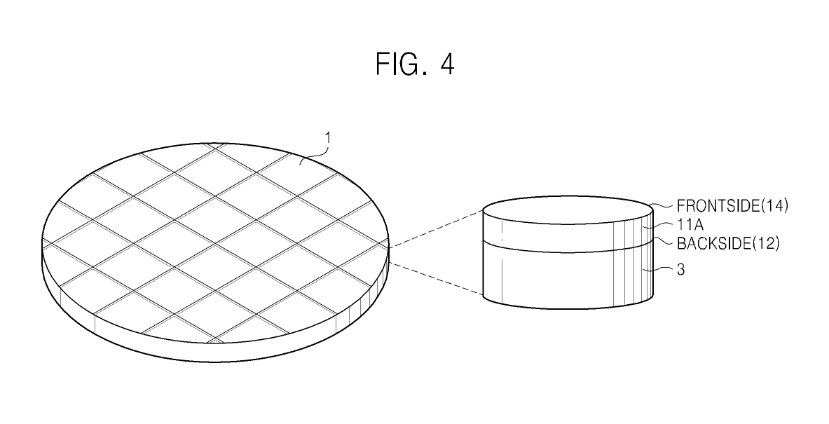

FIGS. 4 through 9 are diagrams that illustrate a method of manufacturing the pixel area 10A illustrated in FIG. 1. Referring to FIGS. 1 and 4, a wafer 1 includes the epitaxial layer 11A disposed on a substrate 3. The epitaxial layer 11A may be formed, for example, by dropping silicon atoms onto the heated wafer 1. The epitaxial layer 11A may have the backside 12 and the frontside 14.

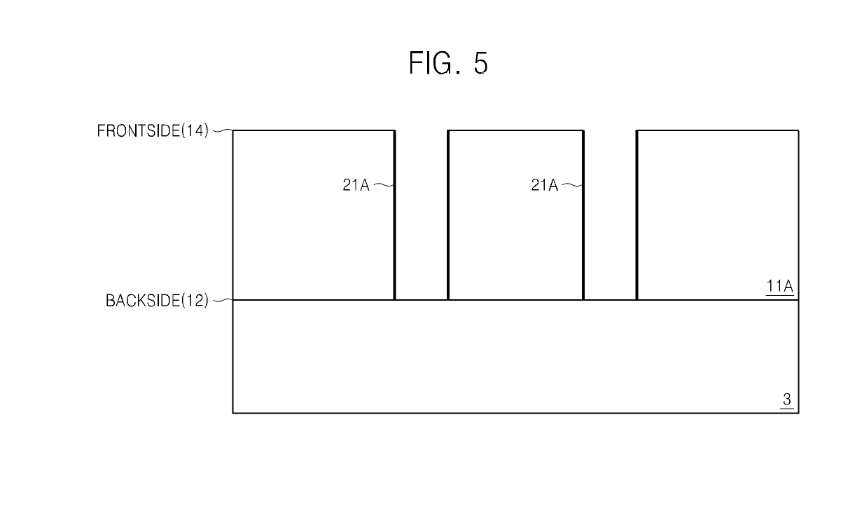

Referring to FIG. 5, the epitaxial layer 11A may be etched to form the trench isolations 21A. A photolithography process, for example, may be used to etch the epitaxial layer 11A. The trench isolations 21A may be formed from the frontside 14 toward the backside 12.

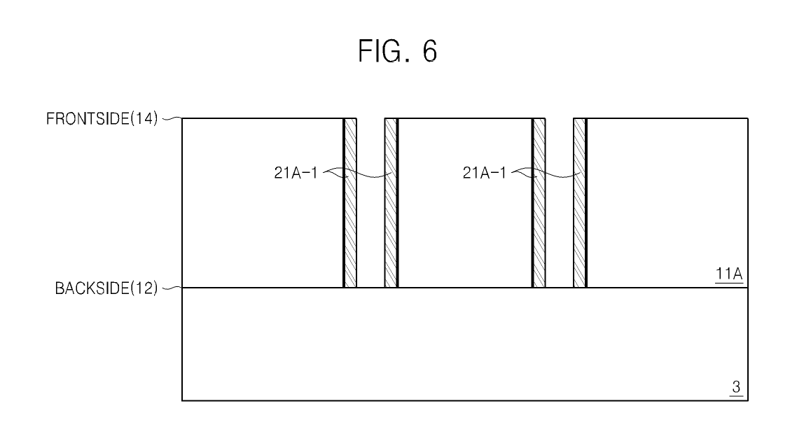

Referring to FIG. 6, the first film 21A-1 may be formed at the inner side of each of the trench isolations 21A. The first film 21A-1 may be formed using, for example, an atomic layer deposition (ALD) process, a diffusion process, a chemical vapor deposition (CVD) process, or a physical vapor deposition (PVD) process.

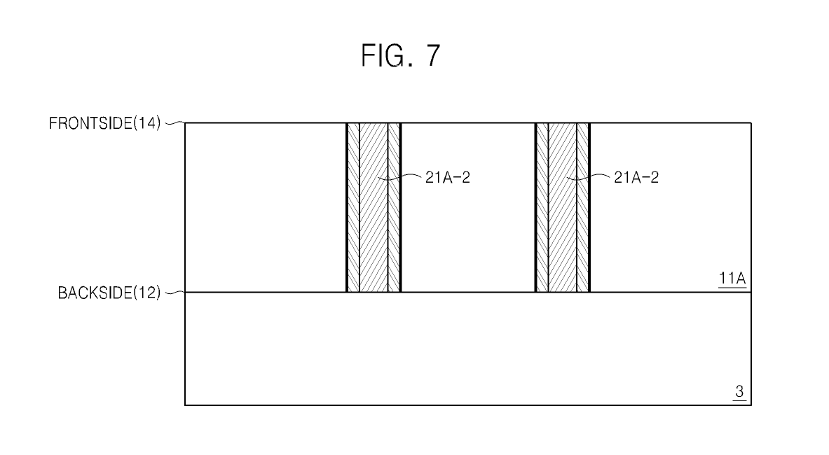

Referring to FIG. 7, the second film 21A-2 may be formed at the inner side of the first film 21A-1. Like the first film 21A-1, the second film 21A-2 may be formed using, for example, an ALD process, a diffusion process, a CVD process, or a PVD process. A chemical mechanical polishing (CMP) process, for example, may also be performed.

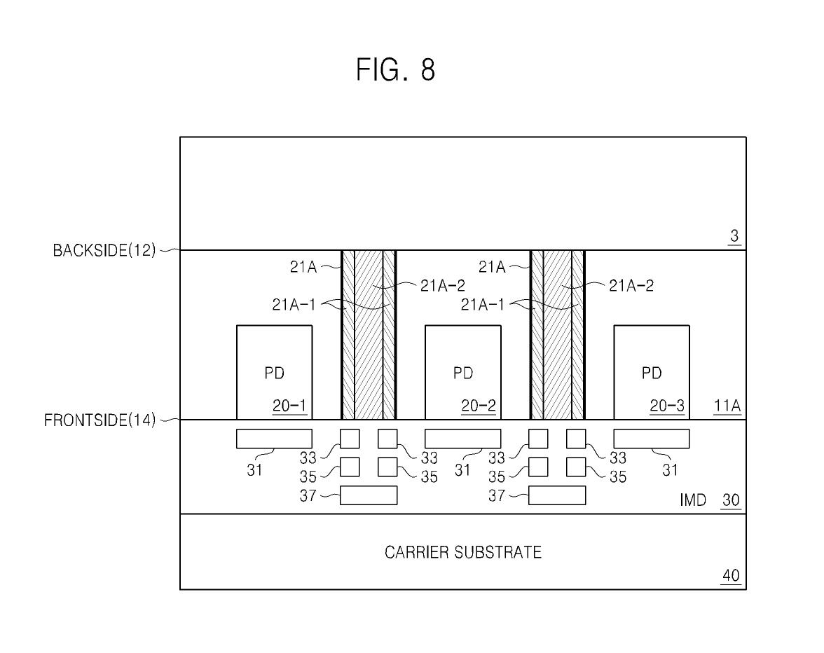

Referring to FIG. 8, the photo detectors 20-1 through 20-3 may be formed in the epitaxial layer 11A in which the trench isolations 21A have been formed. A front-end process and a back-end process, for example, may be performed. After the photo detectors 20-1 through 20-3 are formed, the IMD layer 30 and the carrier substrate 40 may be bonded to the epitaxial layer 11A.

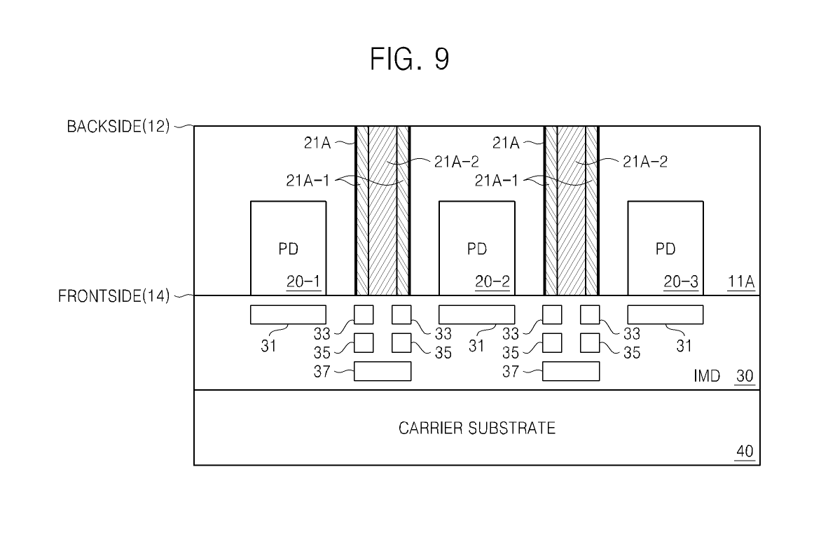

Referring to FIGS. 1 and 9, the substrate 3 may be removed using, for example, a back grinding process. During the back grinding process, the trench isolations 21A may be used as stoppers. As shown in FIG. 1, the anti-reflective layer 50, the color filters 60-1 through 60-3, and the microlenses 70-1 through 70-3 may be formed on the epitaxial layer 11A after the substrate 3 is removed.

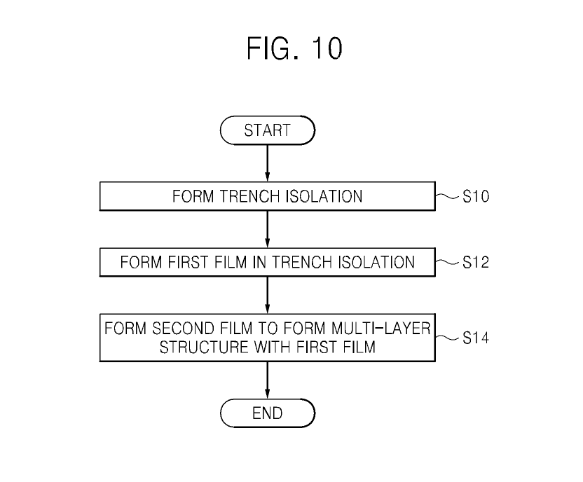

FIG. 10 is a flowchart of a method of manufacturing an image sensor according to an embodiment of the present inventive concept. Referring to FIGS. 4 through 10, the trench isolations 21A may be formed, for example, by etching the epitaxial layer 11A in an operation S10. The trench isolations 21A may be formed, for example, from the frontside 14 of the epitaxial layer 11A toward the backside 12 of the epitaxial layer 11A.

The first film 21A-1 may be formed at the inner side of each of the trench isolations 21A in an operation S12. The second film 21A-2 may be formed at the inner side of the first film 21A-1 in an operation S14. The first film 21A-1 and the second film 21A-2 may be formed in a multi-layer structure. Operations S12 and S14 may be performed using, for example, an ALD process, a diffusion process, a CVD process, or a PVD process.

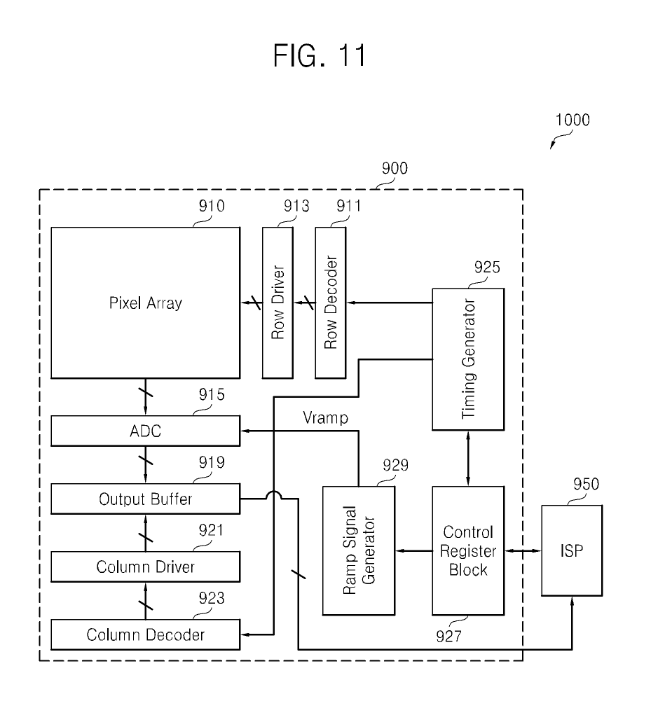

FIG. 11 is a block diagram of an image sensor 1000 including the pixel area 10A illustrated in FIG. 1. Referring to FIGS. 1 and 11, the image sensor 1000 may include a photoelectric conversion circuit 900 and an image signal processor (ISP) 950. The photoelectric conversion circuit 900 and the ISP 950 may be implemented in separated chips, respectively, or may be implemented together in a single chip.

The photoelectric conversion circuit 900 may generate an image signal corresponding to an object in response to incident light. The photoelectric conversion circuit 900 may include a pixel array 910, a row decoder 911, a row driver 913, an analog-to-digital converter (ADC) 915, an output buffer 919, a column driver 921, a column decoder 923, a timing generator 925, a control register block 927, and a ramp signal generator 929.

The cross-section of the pixel array 910 may be implemented, for example, like any one of the pixel areas 10A through 100 illustrated in FIGS. 1 through 3. The pixel array 910 has a matrix form in which a plurality of row lines and a plurality of column lines may be connected with each other.

The row decoder 911 may decode a row control signal (e.g., a row address signal) generated from the timing generator 925. The row driver 913 may select at least one of the row lines in the pixel array 910 in response to the decoded row control signal. The ADC 915 may compare a pixel signal output from a pixel connected to each of the column lines in the pixel array 910 with a ramp signal Vramp and may output a digital signal corresponding to the comparison signal.

The output buffer 919 may buffer and may output the digital signal output from the ADC 915 in response to a column control signal output from the column driver 921. The column driver 921 may selectively activate at least one of the column lines in the pixel array 910 in response to a decoded control signal (e.g., an address signal) output from the column decoder 923. The column decoder 923 may decode a control signal (e.g., an address signal) generated from the timing generator 925.

The timing generator 925 may generate a control signal to control the operation of at least one of the pixel array 910, the row decoder 911, and the column decoder 923 based on a command output from the control register block 927. The control register block 927 may generate various commands to control the elements of the photoelectric conversion circuit 900. The ramp signal generator 929 may output the ramp signal Vramp to the ADC 915 in response to the command output from the control register block 927.

The ISP 950 may generate an image that corresponds to an object based on image signals (e.g., pixel signals) output from the photoelectric conversion circuit 900.

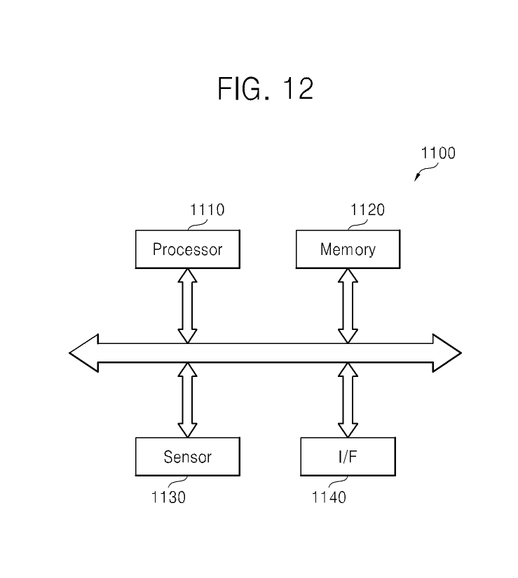

FIG. 12 is a block diagram of an image processing system 1100 including the image sensor 1000 illustrated in FIG. 11 according to an embodiment of the present inventive concept. Referring to FIGS. 11 and 12, the image processing system 1100 may be implemented, for example, as a digital camera, a mobile phone equipped with a digital camera, or an electronic device including a digital camera. The image processing system 1100 may process two-dimensional (2D) image information or three-dimensional (3D) image information. The image processing system 1100 may include a processor 1110, a memory device 1120, an image sensor 1130, and an interface (I/F) 1140.

The processor 1110 may control the overall operation of the image processing system 1100. The memory device 1120 may store a still image or a moving image captured by the image sensor 1130.

The memory device 1120 may be implemented, for example, as a non-volatile memory device. The non-volatile memory device may be implemented using, for example, an electrically erasable programmable read-only memory (EEPROM), a flash memory, a magnetic random access memory (MRAM), a spin-transfer torque MRAM, a conductive bridging RAM (CBRAM), a ferroelectric RAM (FeRAM), a phase-change RAM (PRAM) called ovonic unified memory, a resistive RAM (RRAM or ReRAM), a nanotube RRAM, a polymer RAM (PoRAM), a nano floating gate memory (NFGM), a holographic memory, a molecular electronic memory device, or an insulator resistance change memory.

The image sensor 1130 may be implemented, for example, by the image sensor 1000 illustrated in FIG. 11. The I/F 1140 may interface data between a host (not illustrated), e.g., a display device, and the image processing system 1100. The I/F 1140 may be replaced with a display device (not illustrated).

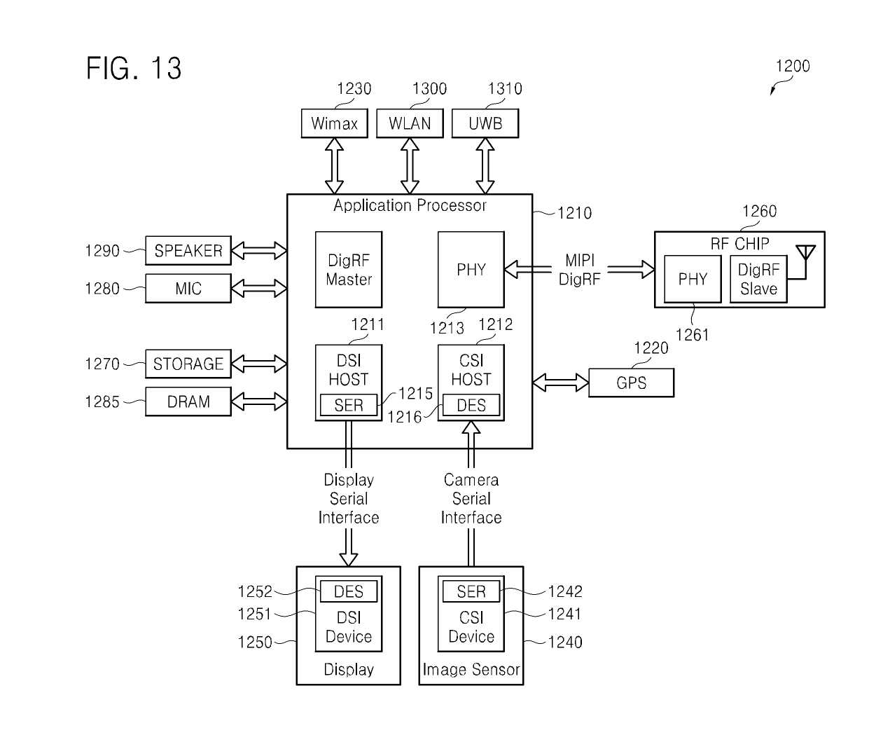

FIG. 13 is a block diagram of an image processing system 1200 including the image sensor 1000 illustrated in FIG. 11 according to an embodiment of the present inventive concept. Referring to FIGS. 11 and 13, the image processing system 1200 may be implemented, for example, as a data processing device, such as a mobile phone, a personal digital assistant (PDA), a portable media player (PMP), or a smart phone, which can use or support, for example, mobile industry processor interface (MIPI®). The image processing system 1200 may include an application processor 1210, an image sensor 1240, and a display 1250.

A camera serial interface (CSI) host 1212 implemented in the application processor 1210 may perform serial communication with a CSI device 1241 included in the image sensor 1240 through a CSI. In this case, for example, an optical deserializer 1216 and an optical serializer 1242 may be implemented in the CSI host 1212 and the CSI device 1241, respectively. The image sensor 1240 may be implemented, for example, by the image sensor 1000 illustrated in FIG. 11.

A display serial interface (DSI) host 1211 implemented in the application processor 1210 may perform serial communication with a DSI device 1251 included in the display 1250 through a DSI. In this case, an optical serializer 1215 and an optical deserializer 1252 may be implemented in the DSI host 1211 and the DSI device 1251, respectively.

The image processing system 1200 may also include a radio frequency (RF) chip 1260 to communicate with the application processor 1210. A physical layer (PHY) 1213 of the application processor 1210 and a PHY 1261 of the RF chip 1260 may communicate data with each other, for example, according to MIPI digital radio frequency (DigRF^{SM}) specifications. The image processing system 1200 may further include, for example, a global positioning system (GPS) 1220, a storage 1270, a microphone (MIC) 1280, a dynamic random access memory (DRAM) 1285, and a speaker 1290. The image processing system 1200 may communicate using, for example, a worldwide interoperability for microwave access (Wimax) standard interface 1230, a wireless local area network (WLAN) interface 1300, and an ultra-wideband (UWB) technology interface 1310.

As described above, according to an embodiment of the present inventive concept, a trench isolation 21A, 21B, or 21C that includes a plurality of films 21A-1 and 21A-2, 21B-1, 21B-2, and 21B-3, or 21C-1, 21C-2, 21C-3, and 21C-4 in a multi-layer structure may be used, so that light incident on the trench isolation 21A, 21B, or 21C may be totally reflected. As a result, light expected to be incident on a particular pixel may be prevented from being input to pixels adjacent to the particular pixel. In addition, an oxide film, for example, that has a negative fixed charge may be used so that the generation of charges may be suppressed in the trench isolation 21A, 21B, or 21C and the charges generated in the trench isolation 21A, 21B, or 21C may be prevented from flowing into a photo detector 20-1, 20-2, or 20-3. As a result, errors caused by dark current may be reduced.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image sensor, comprising:
a plurality of photo detectors; and
a plurality of trench isolations configured to isolate the plurality of photo detectors from each other, each of the trench isolations including a plurality of films in a multi-layer structure.

2. The image sensor of claim 1, wherein the films comprise a first oxide film formed at an inner side of each of the plurality of trench isolations and a poly silicon film formed at an inner side of the first oxide film.

3. The image sensor of claim 2, wherein the films further comprise a nitride film formed between the first oxide film and the poly silicon film.

4. The image sensor of claim 3, wherein the films further comprise a second oxide film formed between the nitride film and the poly silicon film.

5. The image sensor of claim 1, wherein the films comprise a first nitride film formed at an inner side of each of the plurality of trench isolations and a poly silicon film formed at an inner side of the first nitride film.

6. The image sensor of claim 5, wherein the films further comprise an oxide film formed between the first nitride film and the poly silicon film.

7. The image sensor of claim 6, wherein the films further comprise a second nitride film formed between the oxide film and the poly silicon film.

8. The image sensor of claim 1, wherein the films comprise an oxide film formed at an inner side of each of the plurality of trench isolations and a nitride film formed at an inner side of the oxide film.

9. The image sensor of claim 1, wherein the films comprise a nitride film formed at an inner side of each of the plurality of trench isolations and an oxide film formed at an inner side of the nitride film.

10. The image sensor of claim 1, wherein the films comprise an oxide film having a negative fixed charge.

11. The image sensor of claim 10, wherein the oxide film has a stack structure in which a fixed charge film having the negative fixed charge and a silicon oxide film are stacked.

12. The image sensor of claim 11, wherein the fixed charge film is a hafnium oxide film, an aluminum oxide film, a zirconium oxide film, a tantalum oxide film, or a titanium oxide film.

13. The image sensor of claim 1, wherein the films comprise a poly silicon film formed of doped poly silicon.

14. An image processing system, comprising:
the image sensor of claim 1; and
a processor configured to process image signals output from the image sensor.

15. A method of manufacturing an image sensor, the method comprising:
forming a plurality of trench isolations to isolate a plurality of photo detectors from each other;
forming a first film in each of the trench isolations; and
forming a second film that constructs a multi-layer structure together with the first film.

16. An image sensor, comprising:
a first photo detector coupled to a first lens and a second photo detector coupled to a second lens; and
a trench isolation disposed between the first photo detector and the second photo detector and having a material that, in response to a light being incident through the first lens, prevents the light from being input to the second photo detector.

17. The image sensor of claim 16, wherein the material, in response to an electron hole pair being generated in a depletion region of the second photo detector, prevents the electron hole pair from being transmitted to the first photo detector.

18. The image sensor of claim 16, wherein the material comprises a first material having a first refractive index and a second material having a second refractive index.

19. The image sensor of claim 16, wherein the material forms a hole accumulation layer.

20. The image sensor of claim 16, wherein the material includes a fixed charge film having a negative fixed charge.
